(19) United States
(12) Patent Application Publication
(10) Pub. No.: US 2008/0054881 A1
(43) Pub. Date: Mar. 6, 2008

(54) Dc Current Sensor

(76) Inventor: Hyun-Wook Kim, Seoul (KR)

Correspondence Address: IPLA P.A., 3580 WILSHIRE BLVD., 17TH FLOOR, LOS ANGELES, CA, 90010, US

(21) Appl. No.: 11/571,881

(22) PCT Filed: Jul. 7, 2005
(86) PCT No.: PCT/KR05/02189

§ 371 Date: Jan. 9, 2007

(30) Foreign Application Priority Data
Jul. 14, 2004 (KR) 10-2004-0054831

(51) Int. Cl. G01R 33/06

(52) U.S. Cl. 324/117 R

(57) ABSTRACT

Disclosed is a DC current sensor including: a magnetic core symmetrically divided into two parts and having a center space through which a conductive wire carrying DC current to be measured passes; a detection coil wound around one of the magnetic core parts for measuring electromotive force; an operating member installed at the other one of the magnetic core parts repeatedly approach and retreat the magnetic core parts from each other in a non-contact manner; and a controller for controlling the operating member to repeatedly approach and retreat the magnetic core parts from each other to generate electromotive force on a magnetic circuit, wherein there are a pair of gaps between the pair of magnetic core parts, and the generated electromotive force is measured by the detection coil and output from an amplifier circuit to detect the DC current flowing through the conductive wire. Therefore, it is possible to increase detection precision of the DC current sensor by finely controlling the size of the gap.

### TECHNICAL FIELD

The present invention relates to a DC current sensor, and more particularly, to a DC current sensor capable of measuring electromotive force generated by moving a magnetic core having a gap in a non-contact manner to thereby detect DC current.

### BACKGROUND ART

Recently, as devices including an inverter for using DC current, such as electric appliances, electric automobiles, and so on, increase in number, the need for a sensor for detecting a load on a DC motor installed in various devices to perform required control functions, or a DC current sensor used in a DC current interrupter, is increasing.

Some well known types of such a DC current sensor are a magnetic amplifier type, a magnetic multi-vibrator type, a hall device type, and so on.

The hall device type sensor is based on a magnetic resistance effect in which a voltage is output in proportion to magnetic flux by disposing a hall device between ferrite or permalloy-based magnetic core parts spaced apart from each other. Generally, a method of measuring DC current using a non-contact clamp employs the hall device.

The hall device can be applied to various measurement systems by adjusting a gap between the magnetic core parts and substituting materials of the magnetic core parts. However, it is difficult to precisely measure a small current of only several mA using the hall device alone.

### DISCLOSURE OF INVENTION

### Technical Problem

In order to solve this problem, German Patent Laid-open Publication No. DE 31 30 277 A1 discloses a DC current measurement sensor using a soft magnetic core having a slot formed to dispose a hall sensor in a ventilation hole. The current to be measured is guided though a conductor coil surrounding the soft magnetic core, or through an empty space in a ring-shaped core.

However, such a sensor has a complicated structure and can only be realized by using an expensive electronic monitoring device, since a given measurement value is non-linearly dependent on a measurement variable to be determined. In addition, since the measurement result depends on the size of the empty space and the hall sensor, the sensor must be very precisely manufactured.

### Technical Solution

It is an object of the present invention to provide a DC current sensor capable of detecting DC current using a non-contact movement method of periodically reciprocating an upper part and a lower part of a divided magnetic core so that the pair of core parts repeatedly approach and retreat from one another in order to provide a simple structure and excellent current variation detection performance for small to large currents.

It is another object of the present invention to provide a DC current sensor capable of increasing the reliability of a measurement system by enabling adjustment of a measurement region or detection precision because electromotive force can be actively adjusted based on variation of the electromotive force at a constant current becoming larger as a range of movement of the magnetic core parts increases.

It is another object of the present invention to provide a DC current sensor capable of increasing the reliability of a measurement system by enabling adjustment of a measurement region or detection precision because electromotive force can be actively adjusted based on small-scale motion of an oscillator attached to spaced-apart magnetic core parts.

It is another object of the present invention to provide a DC current sensor capable of detecting current at low expense by disposing an oscillator and a magnetic thin layer adhered to each other on a plane to provide a miniaturized thin layer structure.

It is another object of the present invention to provide a DC current sensor capable of providing sufficient output through a simple amplifier circuit and being inexpensive to manufacture due to a good signal-to-noise ratio without a separate filter circuit.

It is another object of the present invention to provide a DC current sensor capable of employing various methods using a solenoid valve, an air pressure cylinder valve, a piezo-electric ceramic oscillator, or the like, as a drive source for operating a magnetic core.

According to an aspect of the present invention, there is provided a DC current sensor including: a magnetic core symmetrically divided into two parts and having a center space through which a conductive wire carrying DC current to be measured passes; a detection coil wound around one of the magnetic core parts for measuring electromotive force; an operating member installed at the other one of the magnetic core parts repeatedly approach and retreat the magnetic core parts from each other in a non-contact manner; and a controller for controlling the operating member to repeatedly approach and retreat the magnetic core parts from each other to generate electromotive force on a magnetic circuit, wherein there are a pair of gaps between the pair of magnetic core parts, the generated electromotive force is measured by the detection coil and output from an amplifier circuit to detect the DC current flowing through the conductive wire.

In addition, the pair of magnetic core parts are preferably formed of a ring-shaped soft magnetic material.

Preferably, the operating member moves the other magnetic core part up and down in order to generate the electromotive force which is proportional to the DC current to be measured.

Preferably, the controller controls detection precision of the sensor by adjusting a range of movement of the second magnetic core part using the operating member.

According to another aspect of the present invention, there is provided a DC current sensor including: a magnetic core having an annular structure, a gap at one side, and a conductive wire carrying DC current to be measured passing through its center space; a detection coil installed at the gap of the magnetic core for measuring electromotive force; an operating member for repeatedly moving the detection coil back and forth with respect to the magnetic core in a non-contact manner; and a controller for controlling the operating member to repeatedly move the detection coil back and forth with respect to the magnetic core to generate electromotive force on a magnetic circuit, wherein the generated electromotive force is measured using the detection coil to detect the DC current flowing through the conductive wire.

Preferably, the operating member moves the detection coil vertically or horizontally in order to generate the electromotive force which is proportion to the DC current to be measured.

Preferably, the controller controls detection precision of the sensor by adjusting a movement range of the detection coil using the operating member.

Preferably, the DC current sensor can detect a wide range of DC current, from a small current of several milli Amps to a large current of several Amps, by adjusting the number of windings of the detection coil.

Preferably, the controller controls on/off operation of the magnetic circuit for electromotive force-generating motion using magnetic flux through the magnetic core.

According to yet another aspect of the present invention, there is provided a DC current sensor including: a magnetic core having an annular structure, a gap at one side, and a conductive wire carrying DC current to be measured passing through its center space; a detection coil for measuring electromotive force wound around one side of the magnetic core to measure electromotive force; an operating member installed at the other side of the magnetic core to repeatedly vary the size of the gap of the magnetic core; and a controller for controlling the operating member to oscillate the size of the gap of the magnetic coil to generate electromotive force on a magnetic circuit, wherein the generated electromotive force is measured using the detection coil and output from an amplifier circuit to detect the DC current flowing through the conductive wire.

According to still another aspect of the present invention, there is provided a DC current sensor including: a magnetic core having an annular structure, a gap at one side, and a conductive wire carrying DC current to be measured passing through its center space; an oscillating member installed around the perimeter of the magnetic core to oscillate the size of the gap of the magnetic core; a detection coil for measuring electromotive force wound on one side of the magnetic core and the oscillating member; and a controller for controlling the oscillating member to oscillate the size of the gap of the magnetic coil to generate electromotive force on a magnetic circuit, wherein the generated electromotive force is measured using the detection coil and output from an amplifier circuit to detect the DC current flowing through the conductive wire.

The oscillating member may be installed inside or outside the magnetic core.

Preferably, the size of the gap can be adjusted.

According to still another aspect of the present invention, there is provided a DC current sensor including: a magnetic core having an annular structure having a plurality of slots formed in a radial direction and a conductive wire carrying current to be measured passing through its center space; an oscillating member installed to form a layered structure together with the magnetic core for oscillating the width of the slots; a detection coil for measuring electromotive force wound on one side of the magnetic core and the oscillating member; and a controller for controlling the oscillating member to oscillate the width of the slots of the magnetic coil to generate electromotive force on a magnetic circuit, wherein the generated electromotive force is measured using the detection coil and output from an amplifier circuit to detect the DC current flowing through the conductive wire.

The oscillating member may be installed at an upper or lower part of the magnetic core.

According to still yet another aspect of the present invention, there is provided a DC current sensor including: a pair of magnetic core parts having a center space through which a conductive wire carrying current to be measured passes; a detection coil wound around one of the magnetic core parts for measuring electromotive force; an oscillating member installed at the other one of the magnetic core parts to repeatedly reciprocate the other magnetic core part back and forth in a non-contact manner; and a controller for controlling the oscillating member to repeatedly reciprocate the other magnetic core part back and forth to generate the electromotive force on a magnetic circuit, wherein the oscillating member and the magnetic core parts form a gap therebetween, the oscillating member includes an oscillator mounted on a plane and a magnetic thin layer coated on a surface of the oscillator, the generated electromotive force is measured by the detection coil and output from an amplifier circuit to detect the DC current flowing through the conductive wire.

The magnetic thin layer is formed of one of Ni and NiFe.

### BRIEF DESCRIPTION OF THE DRAWINGS

The foregoing and other objects, features, and advantages of the present invention will become more apparent from the following detailed description when taken in conjunction with the accompanying drawings in which:

FIG. 1 illustrates a structure of a DC current sensor in accordance with a first embodiment of the present invention;

FIG. 2 illustrates a DC current sensor in accordance with a first embodiment of the present invention;

FIG. 3 illustrates operation of a DC current sensor in accordance with a first embodiment of the present invention;

FIG. 4 illustrates a structure of a DC current sensor in accordance with a second embodiment of the present invention;

FIG. 5 illustrates a structure of a DC current sensor in accordance with a third embodiment of the present invention;

FIG. 6 illustrates a structure of a DC current sensor in accordance with a fourth embodiment of the present invention;

FIG. 7 illustrates a structure of a DC current sensor in accordance with a fifth embodiment of the present invention;

FIG. 8 illustrates a structure of a DC current sensor in accordance with a sixth embodiment of the present invention; and

FIG. 9 is a flowchart illustrating operation of a DC current sensor in accordance with the present invention.

### BEST MODE FOR CARRYING OUT THE INVENTION

Reference will now be made in detail to preferred embodiments of the present invention.

In the following description of the present invention, like reference numerals designate like elements throughout the specification.

Hereinafter, a first embodiment of the present invention will be described with reference to the accompanying drawings.

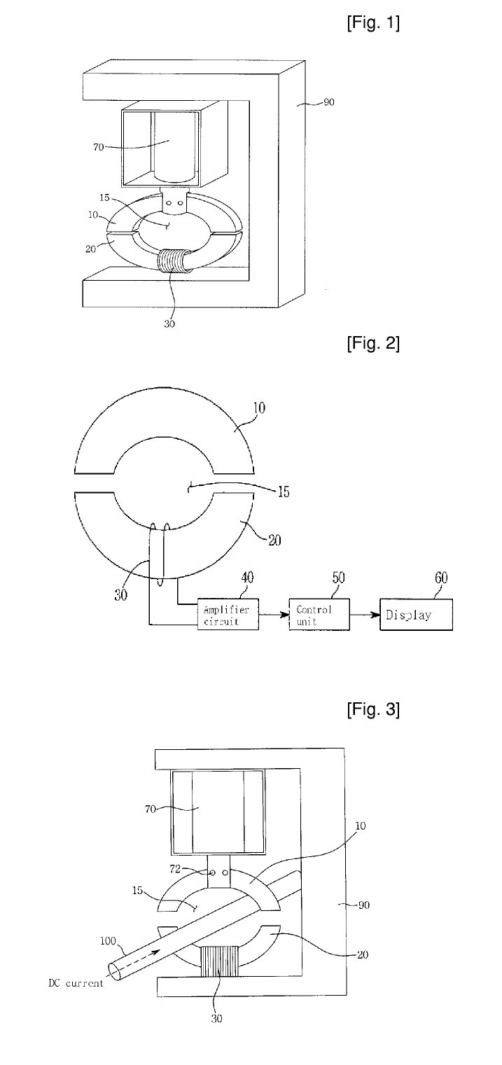

FIG. 1 illustrates a structure of a DC current sensor in accordance with a first embodiment of the present invention, FIG. 2 illustrates a DC current sensor in accordance with the first embodiment of the present invention, and FIG. 3 illustrates operation of a DC current sensor in accordance with the first embodiment of the present invention.

As shown in FIGS. 1 and 2, a DC current sensor in accordance with the present invention includes a magnetic core made of a soft magnetic material to form an annular shape (or a ring shape) having a space 15 in its center and symmetrically divided into an upper magnetic core part 10 and a lower magnetic core part 20. As a result, a pair of first gaps 140 are formed between the upper and lower magnetic core parts 10 and 20.

While the magnetic core parts 10 and 20 are preferably formed of Permalloy C (70% Ni-5 Mo-4 Cu-bal Fe), in consideration of magnetic characteristics as well as operational performance, they may be formed of a well-known soft magnetic material such as a silicon steel plate, amorphous, electromagnetic soft iron, soft ferrite, or an alloy of the foregoing.

A detection coil 30 is wound around the lower magnetic core part 20 (hereinafter, referred to as a stationary magnetic core part) to measure electromotive force generated by periodically reciprocating the upper magnetic core part 10 so that the pair of core parts 10 and 20 repeatedly approach and retreat from one another in a non-contact manner, within the first gaps 140. The current induced in the detection coil 30 is transmitted to a control unit 50 through an amplifier circuit 40 (for example, a differential amplifier circuit) connected to the detection coil 30 to detect the DC current.

The control unit 50 includes a known circuit for producing a measurement value of the detected DC current, and the measurement value may be supplied to a computer (not shown) or may be selectively displayed on a display 60.

In addition, the control unit 50 controls a magnetic circuit to turn on/off using magnetic flux through the pair of magnetic core parts 10 and 20 by adopting a mechanical method or an electrical circuit.

An operating member 70 is installed at the upper magnetic core part 10 (hereinafter, referred to as an operating magnetic core part) to move the operating magnetic core part 10 up and down, maintaining the first gaps 140 in order to generate electromotive force in proportion to the DC current, which is to be measured. The operating member 70 may be driven by various drive sources such as a solenoid valve, an air pressure cylinder valve, a piezo-electric ceramic oscillator, and the like, operated by on/off switching of a power switch for the operating member in response to a control signal of the control unit 50.

Meanwhile, a support frame 90 functions to fix the operating member 70 and the detection coil 30, and a fastening member 72 functions to fasten the operating magnetic core part 10 to the operating member 70.

The magnetic core parts 10 and 20 may be modified to have another shape, such as a simple circle, and they have an arbitrary cross-section which can be circular, ovular, rectangular, or polygonal, for example.

As shown in FIG. 3, a conductive wire 100 carrying a DC current passes through the center space 15 of the pair of magnetic core parts 10 and 20 having a ring shape and maintaining the first gaps 140. The DC current flowing through the conductive wire 100 is to be measured.

In accordance with the first embodiment of the present invention, the DC current sensor is capable of basically detecting DC current by periodically reciprocating the upper magnetic core part 10 so that the pair of core parts repeatedly approach and retreat from one another in a non-contact manner. In addition, it is possible to implement an inexpensive and reliable DC current measurement system capable of measuring a wide range of current from several mA up to several A, by adding a simple amplifier circuit for signal processing. And, it is possible to fabricate a system having a variable a DC current measurement range.

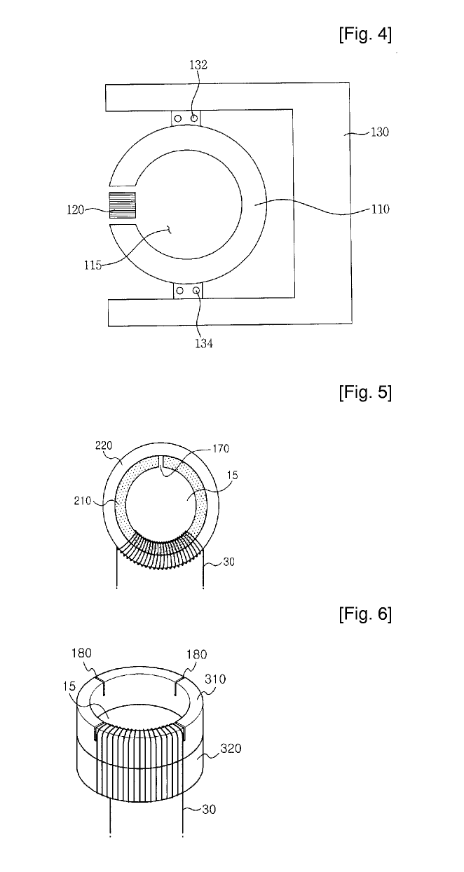

A second embodiment of the present invention will now be described with reference to FIG. 4.

FIG. 4 illustrates a structure of a DC current sensor in accordance with a second embodiment of the present invention.

As shown in FIG. 4, the DC current sensor in accordance with a second embodiment of the present invention includes a magnetic core 110 having a second gap 160 at one side thereof. The magnetic core 110 is made of a soft magnetic material and has an annular shape (or a ring shape) having a center space 115. A detection coil 120 is installed at the second gap 160 of the magnetic core 110 to measure electromotive force generated by periodically reciprocating the detection coil so that it repeatedly approaches and retreats from the magnetic core 110. A signal processing circuit for producing a measurement value from current induced in the detection coil 120 is similar to that used in the system shown in FIG. 2.

An operating member (not shown) is installed at the detection coil 120 to move the detection coil 120 vertically or horizontally to generate electromotive force and a proportional induced DC current which is to be measured. The operating member may be driven by various drive sources such as a solenoid valve, an air pressure cylinder valve, a piezo-electric ceramic oscillator, and the like, operated by on/off switching of a power switch for the operating member in response to a control signal of a control unit 50 (see FIG. 2).

Meanwhile, a support frame 130 supports the magnetic core 110, and fastening members 132 and 134 fasten the magnetic core 110 to the support frame 130.

As described above, while the first embodiment of the present invention detects DC current by measuring electromotive force generated by periodic vertical movement of the operating magnetic core part 10 of the pair of magnetic core parts 10 and 20 having the first gaps 140, the second embodiment of the present invention shown in FIG. 4 can obtain the same effects as the first embodiment by measuring alternating electromotive force generated by periodic vertical or horizontal movement of the detection coil 120 wound at the second gap 160 defined at one side of the magnetic core 110.

A third embodiment of the present invention will now be described with reference to FIG. 5.

FIG. 5 illustrates a structure of a DC current sensor in accordance with a third embodiment of the present invention.

As shown in FIG. 5, the DC current sensor in accordance with a third embodiment of the present invention includes a magnetic core 210 having a third gap 170 at one side thereof, and a piezo-electric oscillator 220 installed around an outer periphery of the magnetic core 210.

That is, the DC current sensor in accordance with the third embodiment has a structure in which the piezo-electric oscillator 220 and the magnetic core 210 are adhered to each other, and the third gap 170 is formed at one side of the magnetic core 210.

However, the arrangement of the magnetic core 210 and the piezo-electric oscillator 220 is not limited to the structure of FIG. 5; alternatively, the magnetic core 210 may be disposed around an outer periphery of the piezo-electric oscillator 220.

In addition, the magnetic core 210 is made of a soft magnetic material and has an annular shape (or a ring shape) having a center space 15, and a detection coil 30 is wound around the magnetic core 210 and the piezo-electric oscillator 220 to measure electromotive force generated by oscillating the size of the third gap 170. A signal processing circuit for producing a measurement value corresponding to current induced in the detection coil 30 is similar to that used in the system shown in FIG. 2.

That is, in accordance with the third embodiment, small-scale movement of the piezo-electric oscillator 220 varies the size of the third gap 170 of the magnetic core 210 to cause magnetic flux variation in proportion to oscillating frequency and thus induce a DC current in the detection coil 30 in a voltage output state.

Therefore, while a conventional magneto-strictive sensor has no secondary effects from formation of a gap since saturation flux density cannot be increased above that of a core of the same size without a gap, the DC current sensor in accordance with the third embodiment of the present invention can increase the saturation flux density by freely varying the size of the third gap 170 formed at the magnetic core 210.

In addition, stress is generated in the magnetic core 210 to advantageously alter magnetic permeability which instantly changes the magnetic flux so that the DC current can be detected.

The other structures and functions of the DC current sensor shown in FIG. 5 are the same as shown in FIGS. 1 to 4.

A fourth embodiment of the present invention will now be described with reference to FIG. 6.

FIG. 6 illustrates a structure of a DC current sensor in accordance with a fourth embodiment of the present invention.

As shown in FIG. 6, the DC current sensor in accordance with the fourth embodiment of the present invention includes a magnetic core 310 having a plurality of slots, i.e., fourth gaps 180, and a piezo-electric oscillator 320 wound around a lower side of the magnetic core 310.

That is, the DC current sensor in accordance with the fourth embodiment has a structure in which the piezo-electric oscillator 320 and the magnetic core 310 are adhered to each other in a layered manner, and the plurality of fourth gaps 180 are formed at the magnetic core 310. Here, the fourth gaps 180 are slots formed in the magnetic core 310 without cutting all the way through, unlike the gaps of the first to third embodiments that pass all the way through the magnetic core.

However, the arrangement of the magnetic core 310 and the piezo-electric oscillator 320 is not limited to the structure of FIG. 6; alternatively, the magnetic core 310 may be disposed under the piezo-electric oscillator 320.

In addition, the magnetic core 310 is made of a soft magnetic material and has an annular shape (or a ring shape) having a center space 15, and a detection coil 30 is wound around the magnetic core 310 and the piezo-electric oscillator 3220 to measure electromotive force generated by oscillating the size of the fourth gaps 180. A signal processing circuit for producing a measurement value from current induced in the detection coil 30 is similar to that used in the system shown in FIG. 2.

That is, in accordance with the third embodiment, small-scale movement of the piezo-electric oscillator 320 changes the width of the slots, i.e., the size of the fourth gaps 180, to cause magnetic flux variation in proportion to oscillating frequency and thus induce a DC current in the detection coil 30 in a voltage output state.

Therefore, the fourth gaps 180 formed at the magnetic core 310 of the fourth embodiment may have a width and number chosen appropriately to increase saturation flux density.

In addition, other characteristics and effects of the fourth embodiment shown in FIG. 6 are the same as those of the structure of FIG. 5, and other structures and functions of the fourth embodiment of FIG. 6 are the same as in the structures of FIGS. 1 to 4.

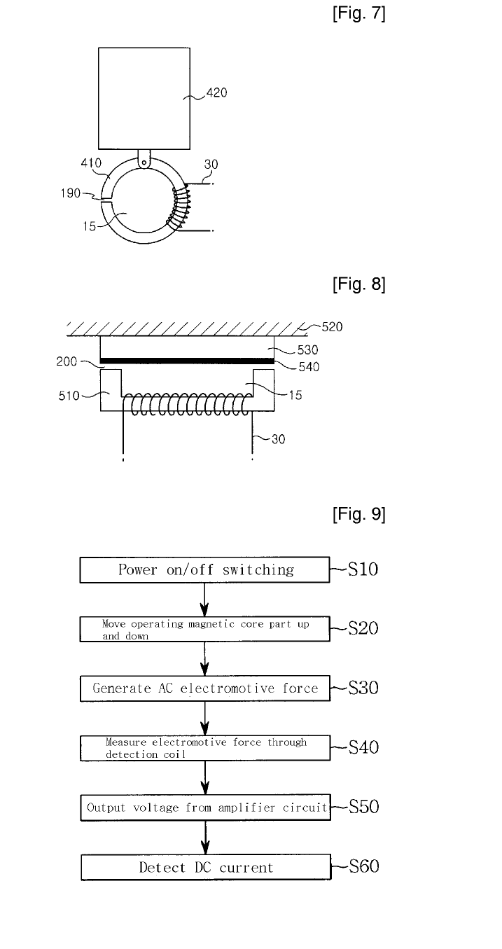

A fifth embodiment of the present invention will now be described with reference to FIG. 7.

FIG. 7 illustrates a structure of a DC current sensor in accordance with a fifth embodiment of the present invention.

As shown in FIG. 7, the DC current sensor in accordance with the fifth embodiment of the present invention includes a magnetic core 410 having a fifth gap 190 at one side and a solenoid oscillator 420 installed at the other side thereof.

The magnetic core 410 is made of a soft magnetic material and has an annular shape (or a ring shape) having a center space 15, and a detection coil 30 is wound around a portion of the magnetic core 410 opposite to the fifth gap 190 to measure electromotive force. A signal processing circuit for producing a measurement value from current induced in the detection coil 30 is similar to that used in the system shown in FIG. 2.

The oscillator 420 oscillates the size of the fifth gap 190 to generate electromotive force and a proportional induced DC current which is to be measured.

That is, the fifth embodiment has the same structure as shown FIG. 1 or FIG. 4, except that the detection coil 30 is wound around the magnetic core 410.

A sixth embodiment of the present invention will now be described with reference to FIG. 8.

FIG. 8 illustrates a structure of a DC current sensor in accordance with a sixth embodiment of the present invention.

As shown in FIG. 8, the DC current sensor in accordance with a sixth embodiment of the present invention includes a piezo-electric oscillator 530 mounted on a plane member 520, an Ni or NiFe magnetic thin layer 540 coated on a surface of the piezo-electric oscillator 530, and a detection coil 30 and a thin layered magnetic core 510 disposed under the magnetic thin layer 540.

While the magnetic core 510 of the sixth embodiment is preferably formed of Permalloy C (70% Ni-5 Mo-4 Cu-bal Fe), it may be formed of known soft magnetic material such as silicon steel plate, amorphous, electromagnetic soft iron, soft ferrite, or an alloy of the foregoing.

In addition, the detection coil 30 is wound around the thin layered magnetic core 510 to measure electromotive force generated by oscillating the size of a sixth gap 200 in a non-contact manner, and a DC current induced in the detection coil 30 is transmitted to a control unit through an amplifier circuit connected to the detection coil 30 to produce a DC current measurement.

Other components such as a signal processing circuit and so on are the same as in the system shown in FIG. 2.

Therefore, the sixth embodiment shown in FIG. 8 has a miniaturized thin layered structure that can be adapted to a semiconductor process, thereby enabling fine adjustment of the sixth gap 200. As a result, it is possible to fabricate a miniaturized DC current sensor capable of detecting DC current at low cost, and to improve detection precision by finely controlling the size of the gap.

Operational effects of the inventive DC current sensor will be described below.

FIG. 9 is a flowchart illustrating operation of a DC current sensor in accordance with the present invention.

Generally, in the case of alternating current, electromotive force is generated in a direction opposing change in magnetic flux, and the current is detected by measuring the electromotive force. However, in the case of direct current, since the flow of current does not change, it is impossible to detect the current using the electromotive force.

Therefore, the DC current sensor of the present invention has a basic structure comprising a magnetic core having a gap at one side and a detection coil wound around the other side. This structure is based on the principal that magnetic flux through the magnetic core is uniform in the case of direct current, the operating magnetic core part or oscillator function to oscillate the magnetic circuit, and the stationary magnetic core part having the winding part functions to detect electromotive force generated in response to oscillation of the magnetic circuit.

Here, the DC current to be measured flows through a conductive wire 100 passing through the magnetic core.

First, in response to a control signal of a control unit 50, a power switch (not shown) for the operating member 70 turns on/off so that the operating member 70 is physically switched on/off (S10).

As the operating member 70 is switched on/off, the operating magnetic core part 10 or the oscillator oscillate causing oscillation in the size of the gap in the magnetic core in a non-contact manner (S20).

Since the magnetic flux through the magnetic core is uniform and proportional to the DC current, the magnetic circuit has no magnetic resistance when the operating magnetic core part and the stationary magnetic core part are close to each other but has magnetic resistance when the magnetic core parts are separated from each other. That is, when the magnetic core parts are reciprocated back and forth to repeatedly approach and retreat from each other, the uniform magnetic flux is disturbed causing an alternating current to flow through the magnetic circuit, thereby generating electromotive force (S30).

At this time, the electromotive force is measured by the detection coil 30 wound around the stationary magnetic core part (S40), and the measured value is output through the amplifier circuit 40 connected to the detection coil 30 as a voltage to be transmitted to the control unit 50 (S50).

The voltage output from the amplifier circuit 40 has a high output ratio to the DC current to enable a sufficiently large output to be obtained using only a simple amplifier circuit 40. Here, a separate filter circuit is not required in a signal processing circuit due to a good signal-to-noise ratio.

Therefore, the control unit 50 detects the DC current as a voltage value transmitted from the amplifier circuit 40 and supplies the voltage value to a computer (not shown) or selectively displays the voltage value on the display 60.

As described above, the DC current sensor in accordance with the present invention employs a method of detecting DC current in a non-contact manner, and the DC current sensor can be attached to the conductive wire 100 carrying the DC current using a clamp, without cutting the conductive wire 100.

In addition, in the DC current sensor of the present invention, the material of the magnetic core, the size of the gap, the number of gaps, and the number of turns in the detection coil 30 can all be appropriately selected so that a wide range of DC current, from several mA to several A, can be measured.

Another major feature of the present invention is that the detection precision can be adjusted. While a current measurement region is limited in the conventional art, the present invention is capable of adjusting the measurement region or the detection precision since variation of electromotive force for uniform current increases as the range of size variation of the gap between the pair of magnetic core parts increases, thereby enabling active adjustment of the electromotive force. Generally, while it is difficult to achieve such functionality and versatility in a measurement system without using additional electrical circuitry, the DC current sensor of the present invention can easily adjust the detection precision and the measurement region to increase reliability of the measurement system.

In addition, since the final output of the present invention is alternating current in proportion to operational frequency of the magnetic core, it is possible to make a good measurement system using a simple circuit that employs a simple amplifier such as a differential amplifier. As a result, it is possible to fabricate a DC current sensor having high detection precision at low cost.

As described in the first embodiment, the DC current sensor of the present invention is capable of detecting DC current in a simple manner by reciprocating upper and lower magnetic core parts so that the size of a gap between the magnetic core parts oscillates. In addition, it is possible to implement an inexpensive and reliable DC current measurement system capable of measuring a wide range of current, from several mA to several A, by using a simple amplifier circuit for signal processing. And, it is also possible to fabricate a system having a variable DC current measurement range.

The voltage output from the DC current sensor of the present invention has a high output ratio to the DC current to enable obtainment of a sufficiently large output using only a simple amplifier circuit 40, and a separate filter circuit is not required in a signal processing circuit due to a good signal-to-noise ratio. In addition, since there is no output when there is no current, no zero point adjustment is required. Further, since the gap between the magnetic core parts can be adjusted to increase output voltage at any given constant DC current, amplification of the output signal can be also adjusted within a certain range.

In addition, the DC current sensor in accordance with the present invention has a relatively simple structure which makes it inexpensive. Mechanical movement may be achieved by employing any of various drive sources such as a solenoid valve, an air pressure cylinder valve, a piezo-electric ceramic valve, and the like.

Further, the DC current sensor in accordance with the present invention has a miniaturized thin layered structure adaptable to a semiconductor process, so that the gap can be finely adjusted, the sensor can be miniaturized at low cost, and detection precision can be increased by fine tuning the gap.

### INDUSTRIAL APPLICABILITY

As can be seen from the foregoing, the DC current sensor in accordance with the present invention can be applied to load detection and control of an apparatus using DC current, such as an electrical appliance, an electric automobile, and so on.

While this invention has been described in connection with what is presently considered to be the most practical and preferred embodiments thereof, it is to be understood that the invention is not limited to these embodiments but rather includes various modifications and alternate embodiments within its spirit and scope defined by the appended claims.

1. A DC current sensor comprising:
a magnetic core symmetrically divided into two parts and having a center space through which a conductive wire carrying DC current to be measured passes;
a detection coil wound around one of the magnetic core parts for measuring electromotive force;
an operating member installed at the other one of the magnetic core parts to repeatedly approach and retreat the magnetic core parts from each other in a non-contact manner; and
a controller for controlling the operating member to repeatedly approach and retreat the magnetic core parts from each other to generate electromotive force on a magnetic circuit,
wherein there are a pair of gaps between the pair of magnetic core parts, and the generated electromotive force is measured by the detection coil and output from an amplifier circuit to detect the DC current flowing through the conductive wire.

2. The DC current sensor according to claim 1, wherein the pair of magnetic core parts are formed of a ring-shaped soft magnetic material.

3. The DC current sensor according to claim 2, wherein the operating member moves the other magnetic core part up and down in order to generate the electromotive force which is proportional to the DC current to be measured.

4. The DC current sensor according to claim 1, wherein the controller controls detection precision of the sensor by adjusting a range of movement of the second magnetic core part using the operating member.

5-7. (canceled)

8. The DC current sensor according to claim 1, wherein the DC current sensor detects a wide range of DC current, from a small current of several milli Amps to a large current of several Amps, by adjusting the number of windings of the detection coil.

9. The DC current sensor according to claim 1, wherein the controller controls on/off operation of the magnetic circuit for electromotive force-generating motion using magnetic flux through the magnetic core.

10. (canceled)

11. A DC current sensor comprising:
a magnetic core having an annular structure a gap at one side, and a conductive wire carrying DC current to be measured passing through its center space;
an oscillating member installed around the perimeter of the magnetic core to oscillate the size of the gap of the magnetic core:
a detection coil for measuring electromotive force wound on one side of the magnetic core and the oscillating member; and
a controller for controlling the oscillating member to oscillate the size of the gap of the magnetic coil to generate electromotive force on a magnetic circuit,
wherein the generated electromotive force is measured using the detection coil and output from an amplifier circuit to detect the DC current flowing through the conductive wire.

12. The DC current sensor according to claim 11, wherein the oscillating member is installed inside the magnetic core.

13. The DC current sensor according to claim 11, wherein the oscillating member is installed outside the magnetic core.

14. The DC current sensor according to claim 11, wherein the size of the gap is adjustable.

15. A DC current sensor comprising:
a magnetic core having an annular structure having a plurality of slots formed in a radial direction and a conductive wire carrying current to be measured passing through its center space;
an oscillating member installed to form a layered structure together with the magnetic core for oscillating the width of the slots;
a detection coil for measuring electromotive force wound on one side of the magnetic core and the oscillating member; and
a controller for controlling the oscillating member to oscillate the width of the slots of the magnetic coil to generate electromotive force on a magnetic circuit,
wherein the generated electromotive force is measured using the detection coil and output from an amplifier circuit to detect the DC current flowing through the conductive wire.

16. The DC current sensor according to claim 15, wherein the oscillating member is installed at a lower part of the magnetic core.

17. The DC current sensor according to claim 15, wherein the oscillating member is installed at an upper part of the magnetic core.

18. The DC current sensor according to claim 15, wherein the width of the slots is adjustable.

19-21. (canceled)
